(19) United States
(12) Patent Application Publication
(10) Pub. No.: US 2007/0090403 A1
(43) Pub. Date: Apr. 26, 2007

(54) Array substrate and method of manufacturing the same

(75) Inventors: Hyun-Jae Ahn, Yongin-si (KR); Hyun-Su Lim, Suwon-si (KR); In-Sung Lee, Seoul (KR); Ki-Wan Ahn, Goyang-si (KR); Jae-Seong Byun, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/543,181

(22) Filed: Oct. 4, 2006

(30) Foreign Application Priority Data
Oct. 20, 2005 (KR) 2005-98951

(51) Int. Cl. H01L 27/10

(52) U.S. Cl. 257/211

(57) ABSTRACT

An array substrate includes a substrate, an electrode pad, an insulating layer and a transparent electrode. The substrate includes a display region and a peripheral region adjacent to the display region. The electrode pad is in the peripheral region. The electrode pad includes a first metal layer and a second metal layer. The second metal layer is on the first metal layer, and includes an opening through which the first metal layer is partially exposed. The insulating layer is on the electrode pad and covers a side surface of the second metal layer in the opening and a portion of the exposed the first metal layer. The transparent electrode is on the insulating layer, and is electrically connected to the first metal layer through a via hole in the insulating layer.

### CROSS-REFERENCE TO RELATED APPLICATION

This application claims priority to Korean Patent Application No. 2005-98951 filed on Oct. 20, 2005, the contents of which are herein incorporated by reference in their entirety.

### BACKGROUND OF THE INVENTION

1. Technical Field

The present disclosure relates to an array substrate and, more particularly, to an array substrate capable of enhancing reliability and a method of manufacturing the array substrate.

2. Discussion of the Related Art

A liquid crystal display (LCD) apparatus may include an array substrate, a color filter substrate facing the array substrate and a liquid crystal layer disposed between the array substrate and color filter substrate.

The array substrate includes a plurality of pixels displaying images. Each of the pixels is a minimum unit for displaying the image. Each of the pixels includes a gate line, a data line, a thin film transistor (TFT) and a pixel electrode. The gate line receives a gate signal. The data line receives a data signal. The thin film transistor is electrically connected to the gate and data lines. The pixel electrode receives the data signal and applies voltage to the liquid crystal layer.

The array substrate may further include a gate electrode pad and a data electrode pad. The gate electrode pad applies the gate signal to the gate line. The data electrode pad applies the data signal to the data line. The gate and data electrode pads are electrically connected to transparent electrodes through via holes, respectively. In addition, the transparent electrodes may be formed on the gate and data electrode pads, respectively.

The gate electrode pad may have a double layered film structure to reduce contact resistance and line resistance between a transparent electrode disposed on the array substrate and the gate electrode pad. For example, the gate electrode pad includes a chromium (Cr) film and an aluminum neodymium (AINd) film.

A gate insulating layer and a passivation layer formed on the gate electrode pad are partially removed and then the AINd film is partially removed to form the via hole. An upper portion of the AINd film making contact with the passivation layer is etched more than a lower portion of the AINd film to form an under-cut.

The transparent electrode on the under-cut may be electrically disconnected to form a crack. A portion of an etchant flows into the under-cut through the crack, and remains in the under-cut to function as an electrolyte so that the transparent electrode is eroded by an ion reaction between the transparent electrode and the AINd layer.

As a result, the transparent electrode is electrically disconnected from the gate electrode pad, thereby decreasing reliability of the array substrate.

### SUMMARY OF THE INVENTION

Embodiments of the present invention provide an array substrate capable of enhancing reliability, a method of manufacturing the above-mentioned array substrate, and a display apparatus having the above-mentioned array substrate.

An array substrate in accordance with an embodiment of the present invention includes a substrate, an electrode pad, an insulating layer and a transparent electrode. The substrate includes a display region and a peripheral region adjacent to the display region. The electrode pad is in the peripheral region. The electrode pad includes a first metal layer and a second metal layer. The second metal layer is on the first metal layer, and includes an opening through which the first metal layer is partially exposed. The insulating layer is on the electrode pad and covers a side surface of the second metal layer in the opening and a portion of exposed the first metal layer. The transparent electrode is on the insulating layer, and is electrically connected to the first metal layer through a via hole in the insulating layer.

A method of manufacturing an array substrate in accordance with an embodiment of the present invention comprises forming an electrode pad in a peripheral region of a substrate, wherein the electrode pad includes a first metal layer, and a second metal layer on the first metal layer. The second metal layer is partially removed to partially expose the first metal layer. An insulating layer is formed on the electrode pad. The insulating layer is pattemed to form a via hole so that the insulating layer covers a side surface of the second metal layer and a portion of the exposed first metal layer. A transparent electrode electrically connected to the first metal layer through the via hole is formed.

An LCD apparatus in accordance with an embodiment of the present invention includes a color filter substrate, an array substrate, a liquid crystal layer and a light generating unit. The array substrate faces the color filter substrate, and includes an electrode pad, an insulating layer and a transparent electrode. The electrode pad has a first metal layer, a second metal layer on the first metal layer. The second metal layer includes an opening through which the first metal layer is partially exposed. The insulating layer is on the electrode pad and covers a side surface of the second metal layer in the opening and a portion of the first metal layer in the opening. The transparent electrode is on the insulating layer, and is electrically connected to the first metal layer through a via hole in the insulating layer. The liquid crystal layer is interposed between the array substrate and the color filter substrate. The light generating unit is disposed under the array substrate and generates light.

The second metal layer of the electrode pad is covered by the insulating layer to prevent erosion caused by an ion reaction between the second metal layer and the transparent electrode, even though a crack may be formed in the transparent electrode on the electrode pad by the under-cut.

### BRIEF DESCRIPTION OF THE DRAWINGS

Exemplary embodiments of the present invention can be understood in more detail from the following descriptions taken in conjunction with the accompanying drawings in which:

FIG. 1 is a cross-sectional view illustrating a liquid crystal display (LCD) apparatus according to an embodiment of the present invention;

FIG. 2 is a plan view illustrating an array substrate in FIG. 1 according to an embodiment of the present invention;

FIG. 3 is an enlarged cross-sectional view illustrating a gate electrode pad in FIG. 1 according to an embodiment of the present invention; and

FIGS. 4A to 4H are cross-sectional views for illustrating a method of manufacturing the array substrate in FIG. 1 according to an embodiment of the present invention.

### DETAILED DESCRIPTION OF THE EXEMPLARY EMBODIMENTS

Exemplary embodiments of the invention are described more fully hereinafter with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

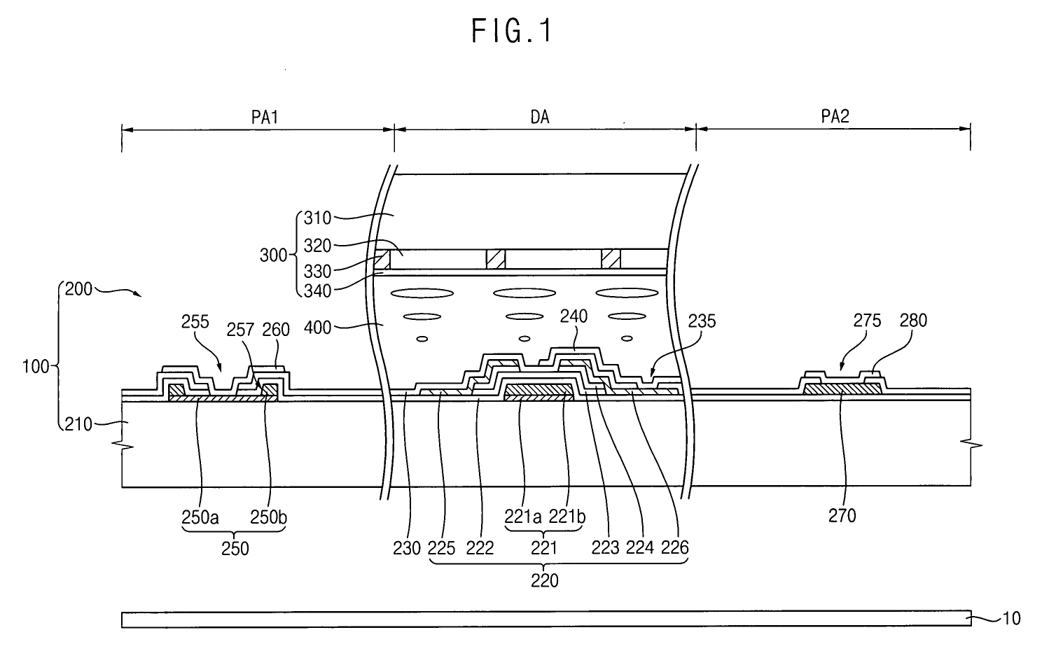

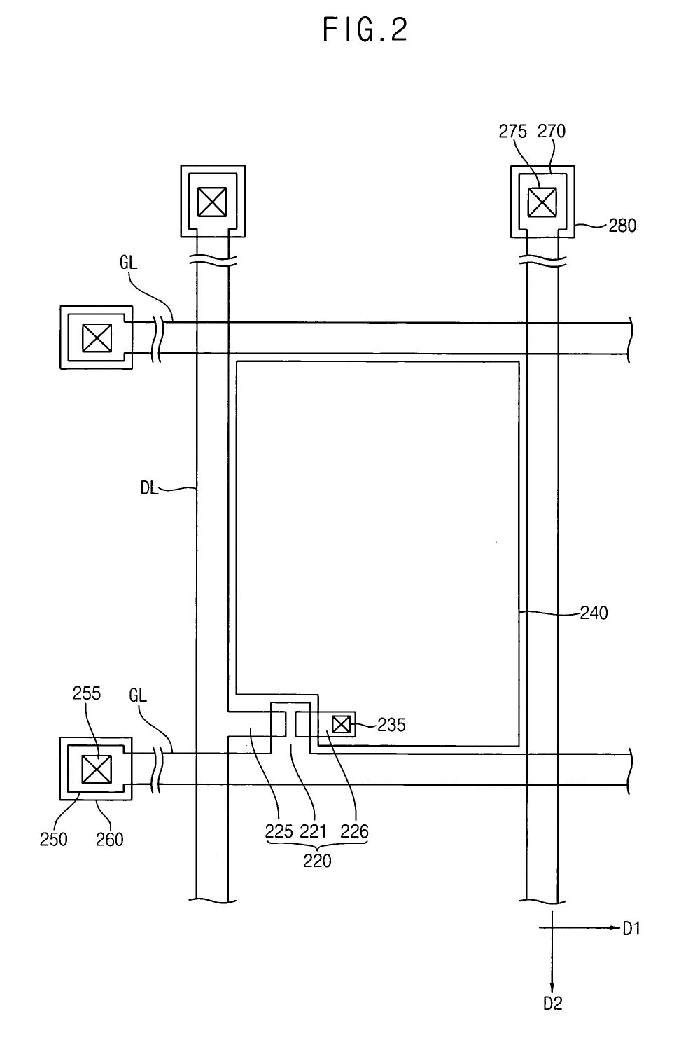

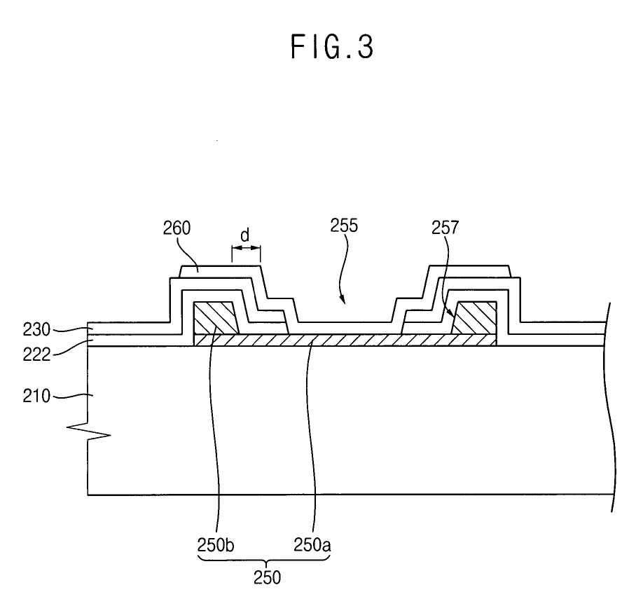

FIG. 1 is a cross-sectional view illustrating a liquid crystal display (LCD) apparatus according to an embodiment of the present invention. FIG. 2 is a plan view illustrating an array substrate in FIG. 1. FIG. 3 is an enlarged cross-sectional view illustrating a gate electrode pad in FIG. 1.

Referring to FIGS. 1 and 2, the LCD apparatus includes an LCD panel 100 displaying an image and a backlight assembly 10 supplying the LCD panel 100 with light.

The LCD panel 100 includes a first substrate, for example, an array substrate 200, a second substrate, for example, a color filter substrate 300, and a liquid crystal layer 400. The color filter substrate 300 faces the array substrate 200. The liquid crystal layer 400 is interposed between the array substrate 200 and the color filter substrate 300.

The LCD panel 100 includes a display region DA displaying the image, a first peripheral region PA1 adjacent to a first side of the display region DA and a second peripheral region PA2 adjacent to a second side of the display region DA.

A plurality of pixel regions are in the display region DA. The pixel regions are defined by a plurality of gate lines GL extending in a first direction D1 and a plurality of data lines DL extending a second direction D2 substantially perpendicular to the first direction D1.

The array substrate 200 includes a first insulating substrate 210, a thin film transistor TFT 220 corresponding to each of the pixel regions, a passivation layer 230 and a pixel electrode 240 corresponding to each of the pixel regions. Alternatively, the array substrate 200 may further include a plurality of TFTs 220 and a plurality of pixel electrodes 240 in each pixel region. The TFT 220 is formed on the first insulating substrate 210. The array substrate 200 may further include an organic insulating layer (not shown) interposed between the passivation layer 230 and the pixel electrode 240.

The TFT 220 includes a gate electrode 221, a gate insulating layer 222, a semiconductor layer 223, an ohmic contact layer 224, a source electrode 225 and a drain electrode 226. The gate electrode 221 is electrically connected to one of the gate lines GL. The source electrode 225 is electrically connected to one of the data lines DL. The drain electrode 226 is electrically connected to the pixel electrode 240.

The gate electrode 221 includes a first gate electrode layer 221a and a second electrode layer 221b deposited on the first gate electrode layer 221a. For example, the first gate electrode layer 221a includes chromium (Cr), and the second gate electrode layer 221b includes aluminum neodymium (AINd).

For example, the source electrode 225 and the drain electrode 226 include chromium (Cr). Alternately, the source electrode 225 and the drain electrode 226 may include chromium (Cr) and/or aluminum neodymium (AINd). The source electrode 225 and the drain electrode 226 may include substantially the same material as the gate electrode 221.

The gate insulating layer 222 is formed on the first insulating substrate 210 having the gate electrode 221. For example, the gate insulating layer 222 includes silicon nitride (SiNx). The semiconductor layer 223 and the ohmic contact layer 224 are formed on the gate insulating layer 222, in sequence. The semiconductor layer 223 includes, for example, amorphous silicon. The ohmic contact layer 224 includes, for example, n+ amorphous silicon. For example, n-type impurities are implanted into amorphous silicon to form the n+ amorphous silicon. The ohmic contact layer 224 is partially removed so that the semiconductor layer 223 is partially exposed.

The passivation layer 230 is formed on the first insulating substrate 210 having the TFT 220. For example, the passivation layer 230 includes silicon nitride (SiNx). The passivation layer 230 has a contact hole 235 through which the drain electrode 226 of TFT 220 is partially exposed. That is, the passivation layer 230 is partially removed to partially expose the drain electrode 226.

The pixel electrode 240 is formed on the passivation layer 230. The pixel electrode 240 includes a transparent and conductive material capable of transmitting light. Examples of the transparent and conductive material that can be used for the pixel electrode 240 include indium zinc oxide (IZO), and indium tin oxide (ITO). The pixel electrode 240 is electrically connected to the drain electrode 226 through a contact hole 235.

The gate electrode pad 250 is formed in the first peripheral region PA1 of the array substrate 200. The gate electrode pad 250 extends from the gate line GL, and has a greater width than the gate line GL. The gate electrode pad 250 includes a first gate electrode pad layer 250a and a second gate electrode pad layer 250b disposed on the first gate electrode pad layer 250a.

In FIGS. 1 and 2, the gate electrode pad 250 is formed from substantially the same layer as the gate electrode 221, and includes substantially the same material as the gate electrode 221. The gate electrode pad 250 may be formed through substantially the same process as for forming the gate electrode 221. For example, the gate electrode pad layer 250a includes chromium (Cr), and the second gate electrode pad layer 250b includes aluminum neodymium (AINd).

A first via hole 255 through which the gate electrode pad 250 is partially exposed is formed in the first peripheral region PA1. The gate insulating layer 222 and the passivation layer 230 on the gate electrode pad 250, and the second gate electrode pad layer 250b are partially removed to form the first via hole 255. The second gate electrode pad layer 250b includes an opening 257 that surrounds the first via hole 255. The first gate electrode pad layer 250a is partially exposed through the opening 257 of the second gate electrode pad layer 250b. The gate insulating layer 222 and the passivation layer 230 extend toward a center of the first via hole 255 with respect to the second gate electrode pad layer 250b. Thus, the gate insulating layer 222 and the passivation layer 230 cover a peripheral portion of the first via hole 255 so that the gate insulating layer 222 and the passivation layer 230 cover a side surface of the second electrode pad layer 250b in the opening 257 and a portion of the first gate electrode pad layer 250a in the opening 257.

The first transparent electrode 260 is formed on the gate electrode pad 250. The first transparent electrode 260 is electrically connected to the first electrode pad layer 250a through the first via hole 255. The first transparent electrode 260 is formed from substantially the same layer as the pixel electrode 240, and includes substantially the same material as the pixel electrode 240. The first transparent electrode 260 may be formed through substantially the same process for forming the pixel electrode 240. For example, the first transparent electrode 260 includes indium tin oxide (ITO) or indium zinc oxide (IZO).

The gate insulating layer 222 and the passivation layer 230 cover the side surface of the second gate electrode pad layer 250b in the opening 257 so that the first transparent electrode 260 does not directly contact with the second electrode pad layer 250b. In FIG. 3, the first transparent electrode 260 is spaced apart from the second gate electrode pad layer 250b by a first distance d. The first distance d is substantially equal to the sum of a thickness of the gate insulating layer 222 and a thickness of the passivation layer 230.

As a result, an erosion of the first transparent electrode 260 is prevented so that the gate signal can be properly applied to gate electrode pad 250. That is, although a crack may be formed at the first transparent electrode 260 by an under-cut of the gate electrode pad 250, and an etchant may flow into the under-cut through the crack, the first transparent electrode 260 is spaced apart from the second gate electrode pad layer 250b to prevent an ion reaction between the transparent electrode 260 and the second gate electrode pad layer 250b, thereby preventing the erosion of the first transparent electrode 260. Therefore, reliability of the LCD apparatus is enhanced.

The data electrode pad 270 is formed in the second peripheral region PA2 of the array substrate 200. The data electrode pad 270 extends from the data line DL, and has a greater width than the data line DL. The data electrode pad 270 is formed from substantially the same layer as the source electrode 225 and the drain electrode 226, and includes substantially the same material as the source electrode 225 and the drain electrode 226. The data electrode pad 270 may be formed through substantially the same process for forming the source electrode 225 and the drain electrode 226. For example, the data electrode pad 270 includes chromium (Cr).

A second via hole 275 through which the data electrode pad 270 is partially exposed is formed in the second peripheral region PA2. The passivation layer 230 on the data electrode pad 270 is partially removed to form the second via hole 275. A second transparent electrode 280 is formed on the data electrode pad 270. The second transparent electrode 280 is electrically connected to the data electrode pad 270 through the second via hole 275. The second transparent electrode 280 includes, for example, indium tin oxide (ITO) or indium zinc oxide (IZO).

Each of the gate electrode pad 250 and the data electrode pad 270 is electrically connected to a printed circuit board, for example, a flexible printed circuit board (not shown) through, for example, an anisotropic conductive film (ACF). The gate electrode pad 250 and the data electrode pad 270 apply gate and data signals from the flexible printed circuit board to the gate and data lines, respectively.

The color filter substrate 300 includes a second insulating substrate 310, a black matrix 320 on the second insulating substrate 310, a color filter 330 and a common electrode 340. The color filter 330 includes red (R), green (G) and blue (B) color filter portions. The black matrix 320 is formed between the R, G and B color filter portions as a matrix configuration to prevent light from exiting a region between the R, G and B color filter portions. The common electrode 340 corresponds to the pixel electrode 240 of the array substrate 200.

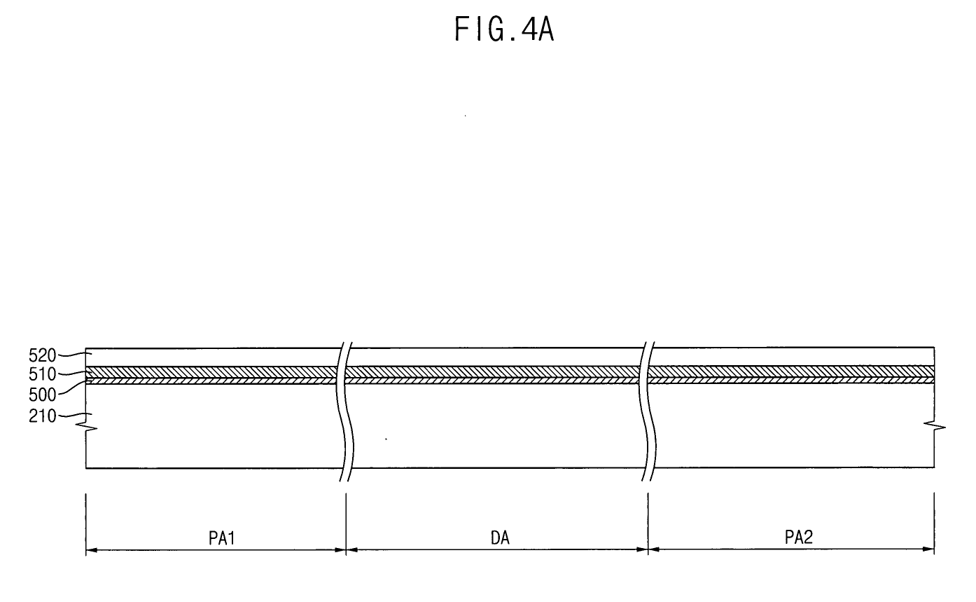

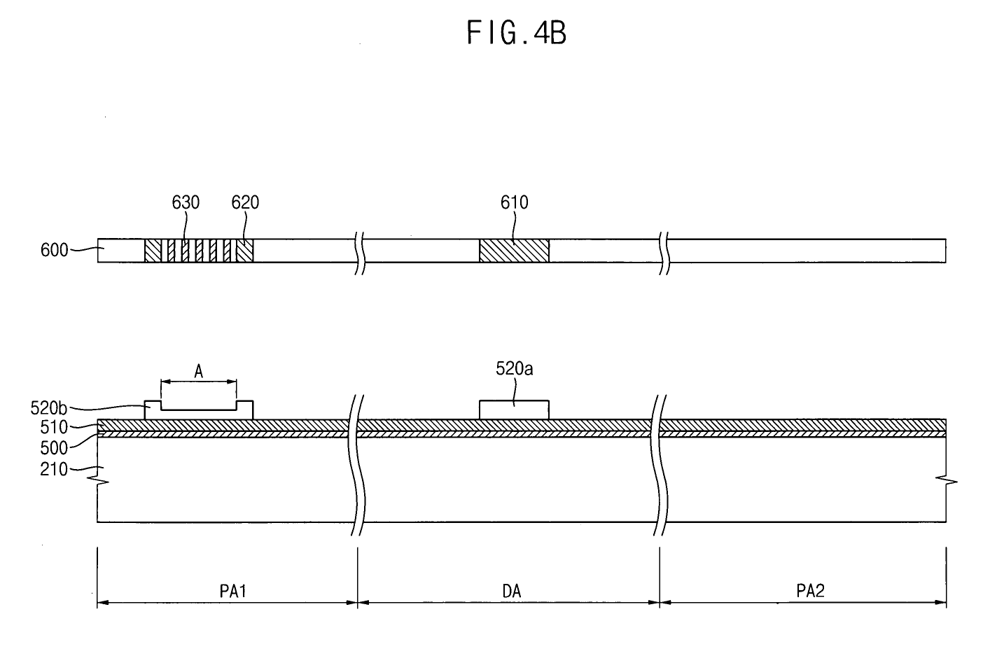

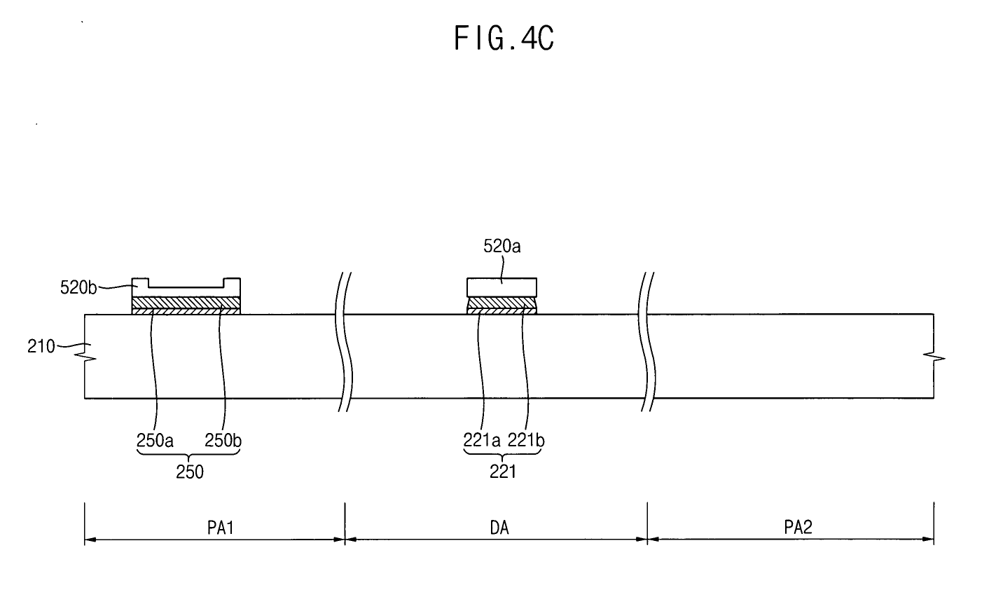

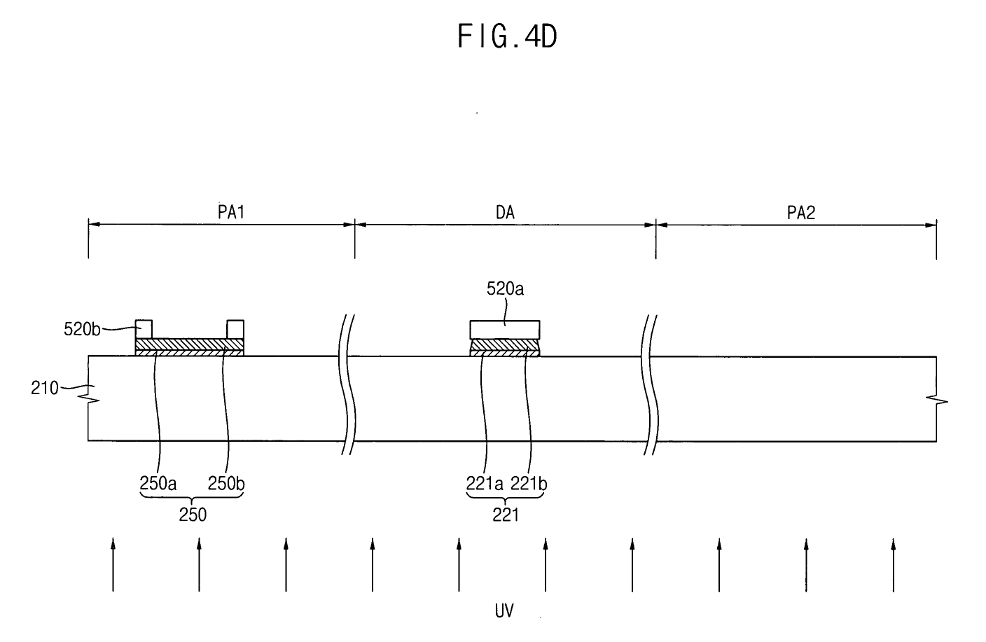

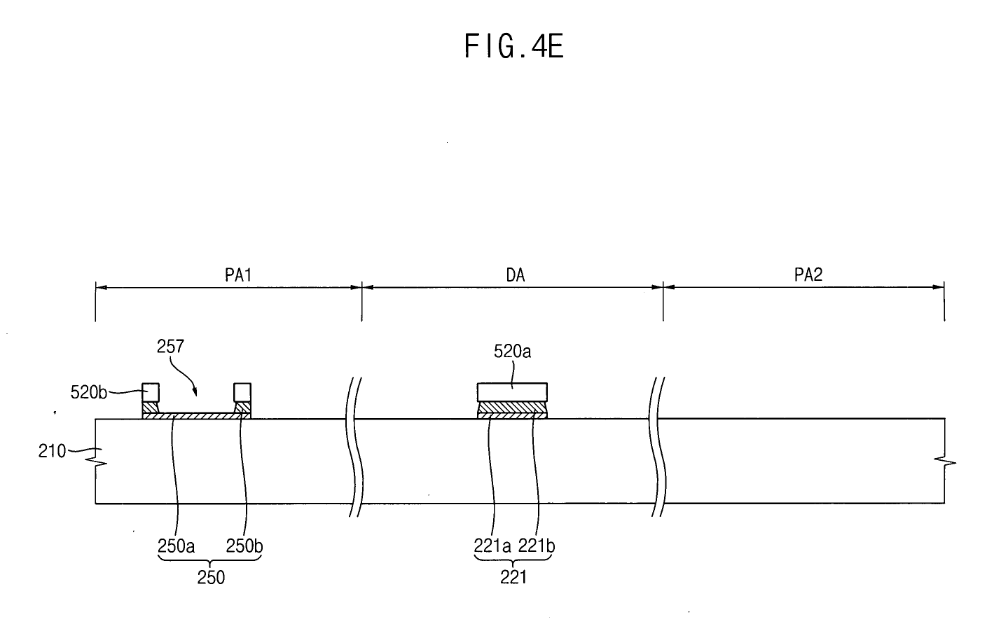

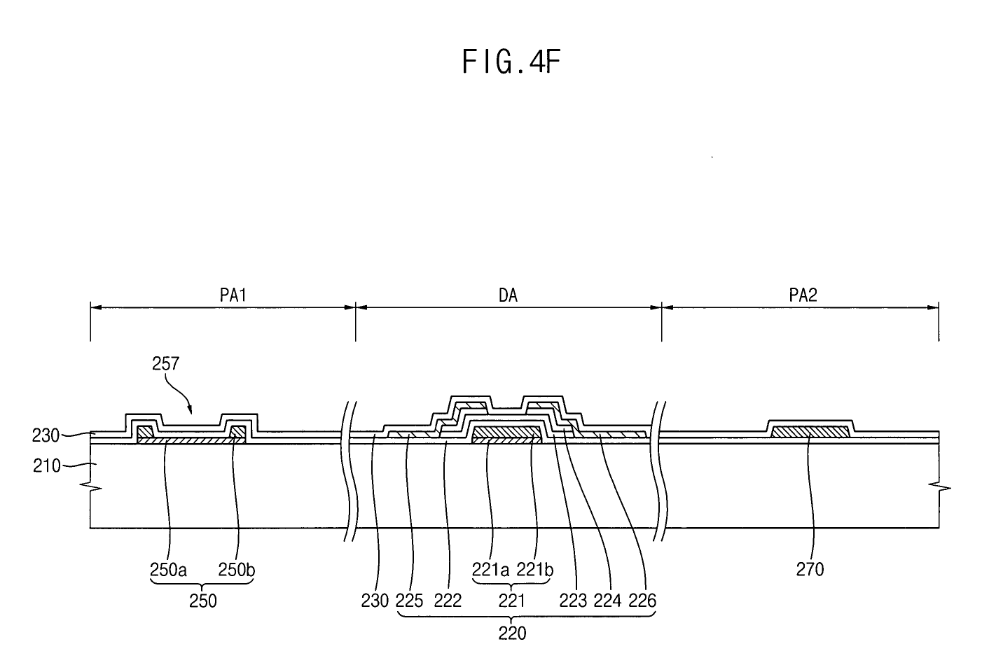

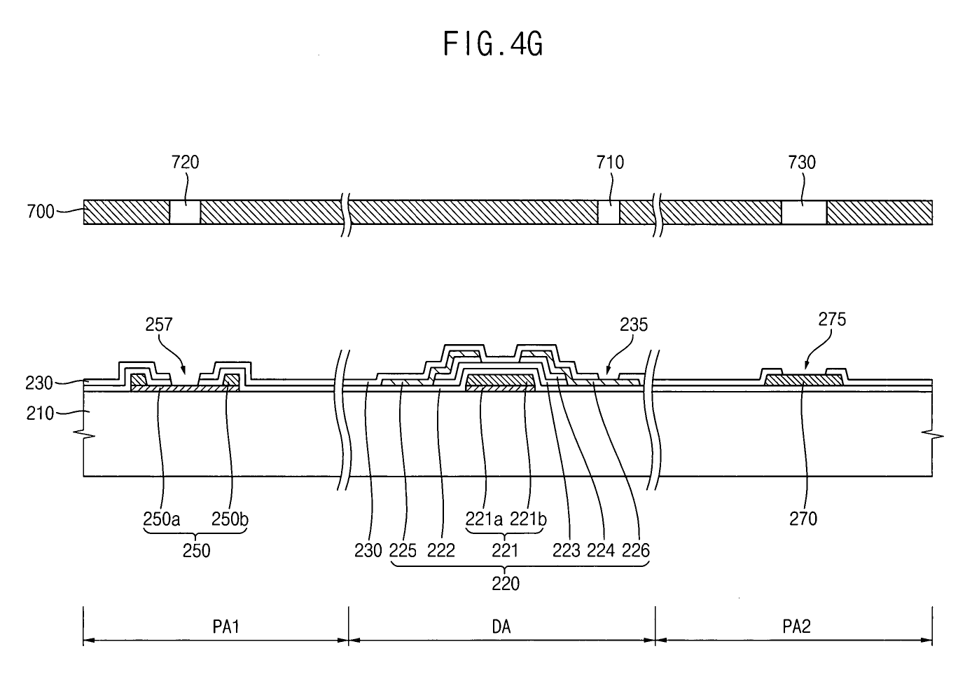

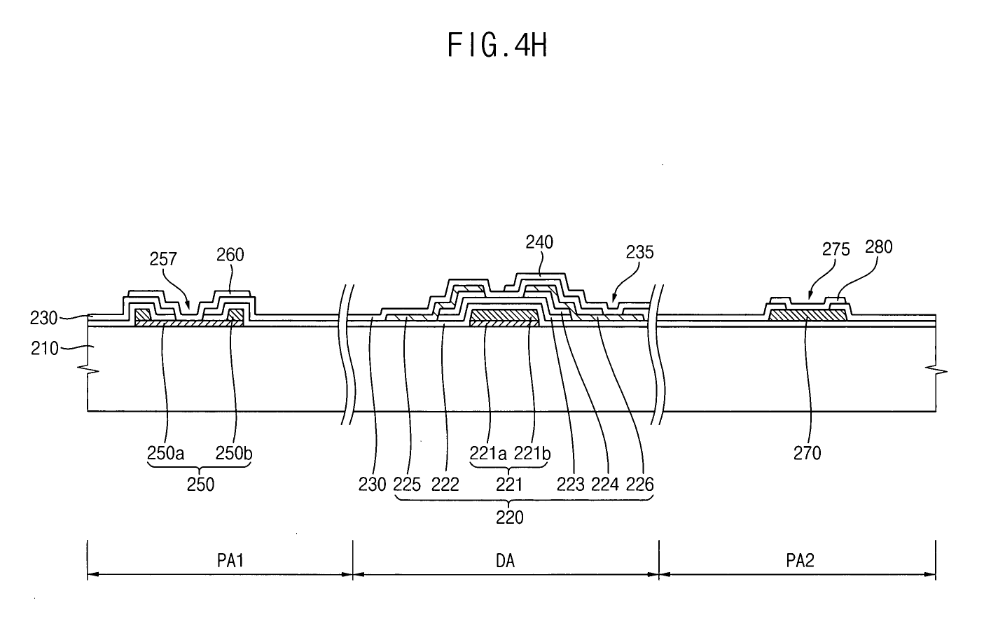

FIGS. 4A to 4H are cross-sectional views for illustrating a method of manufacturing the array substrate in FIG. 1.

Referring FIG. 4A, a first metal layer 500 is deposited on the first insulating substrate 210 by a chromium (Cr)-target sputtering process or a chemical vapor deposition process. A second metal layer 510 is deposited on the first insulating substrate 210 having the first metal layer 500. The second metal layer 510 includes, for example, aluminum neodymium (AINd). A photoresist film 520 having a photosensitive material is coated on the second metal layer 510.

Referring to FIG. 4B, a first mask 600 having a predetermined pattern is aligned with the first insulating substrate 210 having the photoresist film 520. The first mask 600 has a first opaque portion 610 corresponding to the gate electrode 221, a second opaque portion 620 corresponding to the gate electrode pad 250 and a slit pattern 630 corresponding to the first via hole 255.

The photoresist film 520 is exposed to light using the first mask 600 as a photo mask. The photoresist film 520 is developed by a developing agent. In FIG. 4B, the photoresist film 520 includes a positive photoresist of which the exposed region is removed. Thus, a first photoresist pattern 520a is formed in an area corresponding to the first opaque portion 610, and a second photoresist pattern 520b is formed in an area corresponding to the second opaque portion 620. The first photoresist pattern 520a is formed in the display region DA, and the second photoresist pattern 520b is formed in the first peripheral region PA1. In addition, the second photoresist pattern 520b includes a stepped portion. That is, a portion of the second photoresist pattern 520b corresponding to the slit pattern 630 is partially removed so that the second photoresist pattern 520b has a slit area A having a relatively lower height than the first photoresist pattern 520a.

Referring to FIG. 4C, the first and second metal layers 500 and 510 are partially etched using an etchant to form the gate electrode 221 and the gate electrode pad 250. The gate electrode 221 includes the first gate electrode layer 221a and the second gate electrode layer 221b. The first gate electrode layer 221a includes, for example, chromium (Cr), and the second gate electrode layer 221b includes, for example, aluminum neodymium (AINd).

The gate electrode pad 250 includes the first electrode pad layer 250a and the second gate electrode pad layer 250b. The first gate electrode pad layer 250a includes, for example, chromium (Cr), and the second gate electrode pad layer 250b includes, for example, aluminum neodymium (AINd).

Referring to FIG. 4D, a rear surface of the first insulating substrate 210 having the gate electrode 221 and the gate electrode pad 250 is exposed to light. Intensity of the light irradiated onto the rear surface of the first insulating substrate 210 is lower than that of the light irradiated onto the photoresist film 520 (see FIG. 4B). The exposed second photoresist pattern 520b is then developed using a developing agent so that the portion of the second photoresist pattern 520b corresponding to the slit area A, which has the lower height, is removed. Thus, the portion of the second gate electrode pad layer 250b is exposed.

Referring to FIG. 4E, the exposed portion of the second gate electrode pad layer 250b exposed by the second photoresist pattern 520b is then removed. Thus, a portion of the first gate electrode pad layer 250a is exposed. The first and second photoresist patterns 520a and 520b are then removed.

Referring to FIG. 4F, a silicon nitride (SiNx) layer is deposited on the first insulating substrate 210 having the gate electrode 221 and the gate electrode pad 250 to form the gate insulating layer 222. An amorphous silicon layer and an n-type amorphous silicon layer are deposited on the gate insulating layer 222, in sequence. The deposited amorphous silicon layer and the deposited n-type amorphous silicon layer are patterned to form the semiconductor layer 223 and the ohmic contact layer 224 on the semiconductor layer 223.

A third metal layer (not shown) is deposited on the first insulating substrate 210 having the semiconductor layer 223 and the ohmic contact layer 224. The third metal layer is patterned to form the source electrode 225, the drain electrode 226 and the data electrode pad 270. The source electrode 225 and the drain electrode 226 are in the display region DA. The data electrode pad 270 is in the second peripheral region PA2. The third metal layer includes, for example, chromium (Cr).

TFT 220 including the gate electrode 221, the gate insulating layer 222, the semiconductor layer 223, the ohmic contact layer 224, the source electrode. 225 and the drain electrode 226 is formed in the display region DA on the first insulating substrate 210. The gate electrode pad 250 is in the first peripheral region PA1. The data electrode pad 270 is in the second peripheral region PA2. The passivation layer 230 is formed on the first insulating substrate 210 having the TFT 220, the gate electrode pad 250 and the data electrode pad 270.

Referring to FIG. 4G, a photoresist film (not shown) is coated on the first insulating substrate 210 having the passivation layer 230. A second mask 700 is aligned on the photoresist film. The second mask 700 has a first open portion 710 corresponding to the contact hole 235, a second open portion 720 corresponding to the first via hole 255 and a third open portion 730 corresponding to the second via hole 275.

The photoresist layer is exposed through the second mask 700, and is developed to form a photoresist pattern (not shown). The passivation layer 230 and the gate insulating layer 222 are partially etched by an etchant using the photoresist pattern as an etching mask. Thus, a portion of the passivation layer 230 corresponding to the first open portion 710 is removed to form the contact hole 235 through which the drain electrode 226 is partially exposed.

In addition, a portion of the passivation layer 230 corresponding to the second open portion 720 and a portion of the gate insulating layer 222 corresponding to the second open portion 720 are removed to form the first via hole 255 through which the first gate electrode pad layer 250a is partially exposed. The passivation layer 230 and gate insulating layer 222 cover the side surface of the second electrode pad layer 250b in the opening 257. The gate insulating layer 222 and the passivation layer 230 extend a greater distance toward a center of the first via hole 255 than the second gate electrode pad layer 250b. In FIG. 4G, a size of the first via hole 255 is smaller than that of an opening of the second gate electrode pad layer 250b.

Referring to FIG. 4H, a transparent and conductive layer is deposited on the first insulating substrate 210 having the contact hole 235, and the first and second via holes 255 and 275, and the transparent and conductive layer is patterned. Examples of a transparent and conductive material that can be used for the transparent and conductive layer include indium tin oxide (ITO), and indium zinc oxide (IZO). As a result, the pixel electrode 240 is formed in the display region DA, and the first transparent electrode 260 is formed in the first peripheral region PA1. In addition, the second transparent electrode 280 is formed in the second peripheral region PA2. Therefore, the array substrate is formed.

The pixel electrode 240 is electrically connected to the drain electrode 226 through the contact hole 235. The first transparent electrode 260 is electrically connected to the first gate electrode pad layer 250a through the first via hole 255. The second transparent electrode 280 is electrically connected to the data electrode pad layer 270 through the second via hole 275.

The first transparent electrode 260 does not make direct contact with the second gate electrode pad layer 250b of the gate electrode pad 250. That is, the second gate electrode pad layer 250b is partially covered by the gate insulating layer 222 and the passivation layer 230 so that the first transparent electrode 260 is spaced apart from the second gate electrode pad layer 250b.

In FIGS. 4A to 4H, the gate electrode and the gate electrode pad have a double-layered film structure including the chromium (Cr) layer and the aluminum neodymium (AINd) layer. Each of the source electrode, the drain electrode and data electrode pad may also have a double-layered film structure. When the data electrode pad has the double-layered film structure, the second via hole may also have substantially the same structure as the first via hole.

According to embodiments of the present invention, the array substrate includes the gate electrode and the gate electrode pad having the double-layered film structure that includes a first metal layer and a second metal layer on the first metal layer. The first metal layer may be the chromium layer, and the second metal layer may be the aluminum neodymium layer. The second metal layer is partially patterned, and then the via hole through which the gate electrode pad is partially exposed is formed so that an insulating layer partially covers the second metal layer. The insulating layer may be the gate insulating layer and the passivation layer.

Therefore, although a crack may be formed in the transparent electrode on the gate electrode pad by the under-cut, the ion reaction between the second metal layer that may include the aluminum neodymium layer and the transparent electrode is prevented, thereby preventing the erosion of the transparent electrode. Thus, the reliability of the LCD apparatus is enhanced.

Although the example embodiments of the present invention have been described, it is understood that the present invention should not be limited to these example embodiments but various changes and modifications can be made by one ordinary skilled in the art within the spirit and scope of the present invention as hereinafter claimed.

What is claimed is:

1. An array substrate comprising:
a substrate including a display region and a peripheral region adjacent to the display region;
an electrode pad in the peripheral region, the electrode pad including:
a first metal layer; and
a second metal layer on the first metal layer, the second metal layer including an opening through which the first metal layer is partially exposed;
an insulating layer on the electrode pad and covering a side surface of the second metal layer in the opening and a portion of the exposed first metal layer; and
a transparent electrode on the insulating layer, wherein the transparent electrode is electrically connected to the first metal layer through a via hole in the insulating layer.

2. The array substrate of claim 1, wherein the first metal layer includes chromium (Cr) and the second metal layer includes aluminum neodymium (AlNd).

3. The array substrate of claim 1, further comprising:
a switching element in the display region, the switching element including an electrode having the first metal layer and the second metal layer on the first metal layer; and
a passivation layer on the switching element.

4. The array substrate of claim 3, wherein the electrode pad is a gate electrode pad.

5. The array substrate of claim 3, wherein the electrode pad is a data electrode pad.

6. The array substrate of claim 1, wherein the transparent electrode is spaced apart from the second metal layer by the insulating layer.

7. The array substrate of claim 6, wherein a distance between the transparent electrode and the second metal layer is substantially equal to a thickness of the insulating layer.

8. A method of manufacturing an array substrate, comprising:
forming an electrode pad in a peripheral region of a substrate, the electrode pad including a first metal layer, and a second metal layer on the first metal layer, wherein the second metal layer is partially removed to partially expose the first metal layer;
forming an insulating layer on the electrode pad;
patterning the insulating layer to form a via hole, whereby the insulating layer covers a side surface of the second metal layer and a portion of the exposed first metal layer; and
forming a transparent electrode electrically connected to the first metal layer through the via hole.

9. The method of claim 8, wherein forming the electrode pad comprises:
forming the first metal layer on the substrate;
forming the second metal layer on the first metal layer;
forming a photoresist film on the second metal layer;
patterning the photoresist film using a predetermined mask to form a first photoresist pattern including a slit area having a lower height than a remaining portion of the first photoresist pattern;
patterning the first and second metal layers using the first photoresist pattern to form the electrode pad;
removing a portion of the first photoresist pattern corresponding to the slit area; and
partially removing the second metal layer of the electrode pad using the first photoresist pattern without the slit area to partially expose the first metal layer.

10. The method of claim 9, wherein the mask comprises a slit pattern in the slit area.

11. The method of claim 9, wherein removing the portion of the first photoresist pattern corresponding to the slit area comprises:
exposing a rear surface of the substrate to light; and
developing the first photoresist pattern using a developing agent to partially remove the first photoresist pattern corresponding to the slit area.

12. The method of claim 8, further comprising:
forming a switching element in a display region on the substrate adjacent to the peripheral region, wherein the switching element includes an electrode including the first and second metal layers;
forming the insulating layer on the switching element;
patterning the insulating layer to form a contact hole through which the switching element is partially exposed; and
forming a pixel electrode electrically connected to the switching element through the contact hole.

13. The method of manufacturing an array substrate of claim 8, wherein the first metal layer includes chromium (Cr) and the second metal layer includes aluminum neodymium (AlNd).

14. The method of claim 8, wherein the transparent electrode is spaced apart from the second metal layer by the insulating layer.

15. The method of claim 14, wherein a distance between the transparent electrode and the second metal layer is substantially equal to a thickness of the insulating layer.

16. A liquid crystal display apparatus comprising:
a first substrate;
a second substrate facing the first substrate, the second substrate including:
an electrode pad having a first metal layer, a second metal layer on the first metal layer, the second metal layer including an opening through which the first metal layer is partially exposed;
an insulating layer on the electrode pad and covering a side surface of the second metal layer in the opening and a portion of the first metal layer in the opening; and
a transparent electrode on the insulating layer, wherein the transparent electrode is electrically connected to the first metal layer through a via hole in the insulating layer;
a liquid crystal layer interposed between the second substrate and the first substrate; and
a light generating unit disposed under the second substrate.

17. The liquid crystal display apparatus of claim 16, wherein the transparent electrode is spaced apart from the second metal layer by the insulating layer.

18. The liquid crystal display apparatus of claim 17, wherein a distance between the transparent electrode and the second metal layer is substantially equal to a thickness of the insulating layer.
